(19) United States
(12) Patent Application Publication
(10) Pub. No.: US 2006/0291015 A1
(43) Pub. Date: Dec. 28, 2006

(54) Applying multiple imaging processes to digital images

(75) Inventors: Wooi Yeoh, Rochester, NY (US); Ramesh Nagarajan, Pittsford, NY (US); Clara Cuciurean-Zapan, Fairport, NY (US)

Correspondence Address: PATENT DOCUMENTATION CENTER, XEROX CORPORATION, 100 CLINTON AVE., SOUTH, XEROX SQUARE, 20TH FLOOR, ROCHESTER, NY, 14644, US

(73) Assignee: Xerox Corporation

(21) Appl. No.: 11/166,016

(22) Filed: Jun. 24, 2005

(51) Int. Cl. G03F 3/08

(52) U.S. Cl. 358/518; 358/448

(57) ABSTRACT

Present systems and methods enable user-defined image processing parameters to be applied as intended in some regions of a scanned image without applying them in other regions. More specifically, present systems and methods enable a digital reproduction system to automatically adjust for any inherent interactions between separate image processing modules. Present systems and methods need not be concerned about color adjustments that are made by user-defined settings since the system would automatically adjust for interactions between user-defined settings and automatic adjustments that are made by the system. Present systems and methods provide the flexibility that would be obtained by re-arranging the imaging modules in the processing path of an image processing system.

### TECHNOLOGY

Illustrated herein, generally, are systems and methods for digitally capturing input images. More specifically, present systems and methods may be used to accurately obtain the output that is desired when multiple imaging processes are applied to an image in an image processing pipeline.

### BACKGROUND

Color scanners, printers, copiers and multifunction devices have become increasingly popular in the recent years and companies that manufacture and sell these products are constantly trying to improve image quality. To satisfy consumer demands, color output devices must now be able to generate high quality images with consistent colors, to do so when similar data is printed using a single marking device, different units of the same model marking device or compatible marking devices and do so over an extended period of time.

To provide consistent color images, the colors that are displayed in the original image must be accurately captured and the resulting image data must produce the same colors after being processed by the output device. For example, to print a scanned color image, a scanner may generate RGB data that represents the original image and the RGB data may then be converted to CMYK data that drive the printer to deposit cyan, magenta, yellow and black colorants on the output sheet in the proper proportions. If either the scanner generated RGB data or the printer processed CMYK data is inaccurate, the output image will not match the original.

To improve output quality, scanned image data is often subjected to additional imaging processes. Many of these imaging processes adjust the color values of the scanned image data and they are often applied at different points along the image processing pipeline. For example, skew correction, cropping and other corrections are often automatically applied by the image processor at the front of the pipeline, while those that adjust image color in response to manual, user selected settings often take place toward the end. Unfortunately, color value adjustments that are made by processes that are applied later in the pipeline sometimes interfere with those that are made by processes that are applied earlier.

For example, most scanned images are captured by overscanning the original document to be sure all four edges of the document are contained in the scan. Thus, scanned images typically include “edge blanking;” i.e., black edges that surround the perimeter of the area corresponding to the original document image. Most print engines are incapable of depositing marking material at the outermost edges of the output sheet and thus, “white masking” is usually applied to replace the edge blanking with a blank (usually white) mask.

While white masking is advantageous, it may also have some drawbacks. For example, a user may scan a printed image that includes a white mask, then manually adjust the color of the image. Unfortunately the user selected changes will also be applied to the white region of the scan, which causes an undesirable tint to be displayed near the perimeter of the scan. Further, if the scanned image is then printed, the print engine will insert its own white mask to avoid having to mark the outermost edges of the sheet and a white border will be displayed next to the tinted region of the output image.

It would be beneficial to provide a system and method that processes a scanned image as intended by the user when multiple imaging processes are applied at different points in the image processing pipeline.

### REFERENCES

US Pub. No 2004/0169873 discloses presenting a user with a suggested parameter adjustment to a scanned image upon system analysis of corresponding scanned image data. The suggested adjustment is communicated to the user and the user implements or overrides the suggested adjustment in a subsequent scan of the image.

### SUMMARY

Aspects disclosed herein include a system, with a scan image capture board configured to generate a digital image that represents an image on an original document; and an image processor configured to receive the digital image and prepare the digital image for output, the image processor being further configured to receive an electronic signal associated with a custom image adjustment setting, to calculate a counter-shift image data value corresponding to the received signal and to assign the counter-shift image data value to pixels in the digital image that are selected for processing during an early applied imaging process.

In one aspect, a method includes receiving a digital image; obtaining a customized parameter setting for a second imaging process; using the customized parameter setting to calculate a counter-shift color value for pixels in the digital image that are selected for processing during a first imaging process; assigning the counter-shift color value to the first imaging process selected pixels; and performing the second imaging process on the digital image using at least the customized parameter setting.

In another aspect, an image processor includes an image data input configured to receive a digital image; a user input signal processor configured to receive an electronic signal associated with a user manual adjustment and provide a customized parameter setting corresponding to the user manual adjustment; a color value correction generator configured to calculate a counter-shift color value setting for pixels in the digital image that are selected for processing during a first imaging process; a color value modifier configured to assign the counter-shift color value setting to the first imaging process selected pixels; and an custom output processor configured to apply a next imaging process on the digital image using at least the customized parameter setting.

### BRIEF DESCRIPTION OF THE DRAWINGS

FIG. 1 provides an example of a system for digitally reproducing hardcopy images.

FIG. 2 is a flow diagram showing operation of a typical document scanning process.

FIG. 3 is a flow diagram with a detailed illustration of how color data may be finally processed using present systems and methods.

### DETAILED DESCRIPTION

For a general understanding of the present system and method, reference is made to the drawings. In the drawings, like reference numerals have been used throughout to designate identical elements. In describing the present system and method, the following term(s) have been used in the description:

As used herein, “color” refers to the visual attribute resulting from the light reflected from an object. In a typical color image processing system, color based adjustments are made by changing the values that control the hue, saturation, brightness, and contrast of the image data pixels.

“Hue” refers to the predominant color of the object, i.e., the color within the visible spectrum of light, as defined by its dominant wavelength. For example, a light wave with a dominant wavelength between 565-590 nm will be perceived by the human visual system as yellow. In contrast, “saturation” refers to the color intensity of the object, i.e., the intensity of a specific hue while “brightness” refers to the relative intensity of two objects.

A “digital image” is a representation of a two-dimensional image as a finite set of pixel values. Digital images can be created by digital cameras, scanners, coordinate-measuring machines, seismographic profiling, airborne radar and a variety of other input devices and techniques.

“Image processmg” and an “imaging process” refer to a series of algorithms that are applied a digital image.

An “image processing pipeline” refers generally, to the sequential order of the adjustments that are made to the image data values before the image data is processed for output.

A “grayscale image” is a digital image that has a single channel of color information, typically 8 bits per pixel in a digital system. When displayed, grayscale images are typically composed of shades of gray, varying from black at the weakest intensity to white at the strongest. They could, however, be displayed as shades of any color, or coded with different colors for different intensities.

A digital “color image” is a digital image that has multiple channels of color information. In a computer display, for example, digital color images are commonly provided using the RGB color space and 8 bits are assigned to each of the red, green and blue components of visible light. However, different numbers of bits and/or other spaces such as CIEL*a*b*, YUV, HSB, HSV, YIQ, YCrCb, etc. are often used in other contexts.

A “color value” refers to a composite numerical value that represents the optical density at a specified pixel, which is obtained when multiple monochromatic separations are superimposed. In a RGB color space such as that described above, a color value will typically include 24 bits of information, 8 bits for each of the R, G and B separations.

A “counter-shift color value” refers to a color value that is obtained by automatically adjusting the value provided by an imaging process.

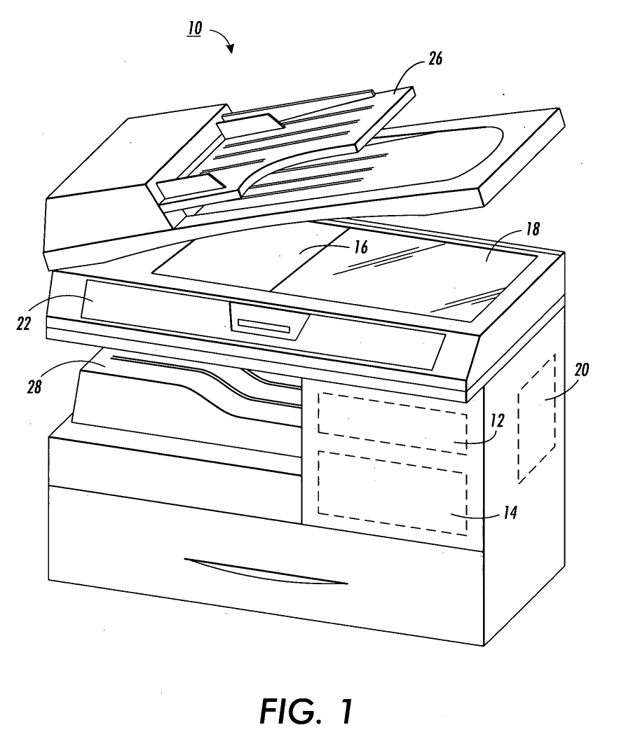

Present systems and methods propose the use of counter-shift color values, to preserve the color settings that are applied by earlier imaging processes when subsequent color adjusting imaging processes are applied to the same image data. While present systems and methods are described herein with reference to the multi-function device (MFD) 10 shown in FIG. 1, it is understood that other imaging systems may also be used, including computer systems and networks have one or more stand alone scanners and/or printers and those with other types of single function devices. In the example shown, MFD 10 includes a scan image capture board 12 that digitally captures images from hardcopy original documents 16 that are positioned on a scanning platen 18 and an image processor (IP) 20 that performs various functions, including converting the image data generated by scan image capture board 12 from a scanner color space such as RGB to a printer color space such as CMYK. MFD 10 also includes a digital color printer 14 that generates hardcopy reproductions of the processed data and has a user interface (UI) 22 with a telecommunications key pad 24 that can be used to establish connections to remote devices over a telecommunications channel. MFD 10 also has a document feeder 26 that can be used to transport original documents 16 to platen 18 and an output tray 28 that can be used to collect hardcopy reproductions.

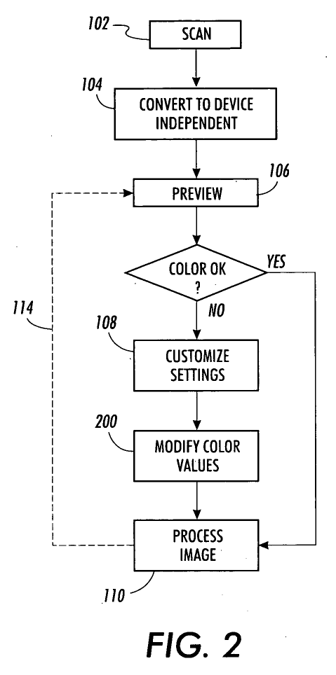

FIG. 2 is a flow diagram showing a typical scanning process. Beginning with block 102, scan image capture board 12 separately records the analog charge values that represent the red (R), green (G) and blue (B) components of visible light reflected from an image displayed on original document 16 and the analog charge values for each component are converted to 8-bit grayscale values. In other words, each pixel in the image is represented by a 24-bit, composite color value.

Grayscale data is often subjected to some form of image processing to prepare the scanned image for output. For example, it is common, but not necessary, to convert the scanner dependent RGB image data to device independent data as shown in block 104, such as CIEL*a*b* which describes each color in terms of its luminance (L*), red-green chrominance (a*) and blue-yellow chroninance (b*). Device independent data can then be converted to device dependent data for output by a selected device. For example, to provide a hardcopy reproduction of the scanned image, the L*a*b* data may be converted to CMYK image data for output by a selected printer. Image data is also usually processed to optimize it for output by a specified program, application and/or device. For example, the color of the image may be optimized by adjusting the color values that are assigned to various image data pixels.

Color adjustments may result from processing that is automatically applied by the system or from processing that requires user input. For example, the white masking process described above is typically automatically applied by IP 20 to image data that will be printed by adjusting the luminance (L*), red-green chrominance (a*) and/or blue-yellow chroninance (b*) values of the device independent data. Adjustments that require user input are also typically applied by adjusting L*, a* and/or b* color values.

A preview of the scanned image data is provided at a video monitor or other suitable device as shown at block 106. If, in the opinion of the user, the preview image provides an accurate representation of the input as shown in block 110 the data is processed as shown at block 112. If the preview image is unacceptable, the user may customize one or more of settings for a predefined set of image processing parameters as shown at block 108, which causes IP 20 to modify the color values for the corresponding pixels as indicated at block 200. More specifically, the user may customize these settings by manually adjusting one or more control(s) at UI 22 to adjust the brightness, hue, contrast, sharpness, saturation, color balance and/or other aspects of the image appearance. Electronic signals that correspond to the magnitude and direction of these user adjustments are forwarded to IP 20, which appropriately modifies the color values for the device independent pixel values as shown in block 200. The image data is then processed as shown in block 112 using the color values that correspond to the adjustments that were made by the user. In some systems the user may preview the image again after modifying the control(s) as indicated by arrow 114, while in some systems, the user may output the image without previewing it again.

Using currently available systems and methods, the results obtained when a user provides customized color settings may be dramatically different depending upon the order in which the various color adjustment processes take place in the image processing path. More specifically, if the user selected settings modify color values that have been set by an earlier applied color adjusting process, the user selected settings may interfere with the colors provided during the earlier applied process.

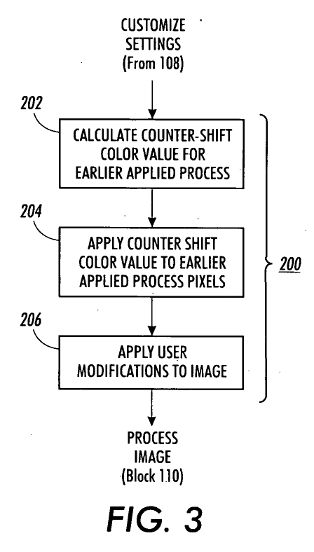

Present systems and methods can be used to provide counter-shift adjustment values based on the underlying the image path implementation to perform the color value modification of block 200 of FIG. 2. Turning to FIG. 3, IP 20 first uses the customized settings selected by the user (FIG. 2, block 108) to calculate a counter-shift setting for each color adjustment parameter that has been applied during an earlier applied process, as shown in block 202. The counter-shift settings are then applied to the scanned image pixels that will be modified during automatically applied image processing as shown in block 204, instead of the settings that are defined by the imaging process. Generally, the counter-shift setting will be the opposite of any image processing parameters that have been modified through user input. The user selected settings are then applied to the entire image as shown in block 206 and the entire image is processed using the customize settings.

For example, a “hue shift” can be applied to uniformly change the color of an image, i.e., to change the color value for each of the image data pixels in a single color vector direction. Notably, a shift in the hue of one portion of an image to match a standard feature or color will typically correct all of the other colors in the image. Referring back to FIG. 2, a user previewing the scanned image as shown in block 106 may decide that the background of a scanned document is discolored and apply a “hue shift” to adjust the color for the entire image. The user can shift the hue of the image until the background color of the document is adjusted to standard white which in turn, will change the color for the entire image. For example, the hue control at UI 22 may be manually adjusted to add blue to whiten the background of the preview image at block 108, which corresponds to a signal generated by IP 20 that shifts the hue angle for the yellow-blue (b*) channel by −23 degrees.

Turning to FIG. 3, continuing with the previously described white masking example, present systems and methods would use the custom b*=−23 degrees hue angle setting to provide a counter-shift hue angle setting of b*+=+23 degrees as shown at block 202. The b*=+23 counter-shift would then be applied to the existing color value for each pixel in the white mask region as shown at block 204. More specifically, the counter-shift setting will be that which provides the desired color value when the user selected adjustments are made to the image. For example, during a typical white masking process, the desired color value for each pixel at the perimeter of the image is L*=100, a*=0, b*=0 in a luminance-chrominance model. However, present systems and methods use the customized −23 counter-shift setting to counter-shift the color value for these pixels to L*=100, a*=0, b*=+23. Thus, when the image is processed using the b*=−23 customized setting, the final color value for each pixel in the mask region will be L*=100, a*=0, b*=0. The user selected settings are then applied to the entire image as shown in block 206 and the entire image is processed using the customize settings. Accordingly, both the user selected color changes and the original mask color are maintained in the desired locations.

While present systems and methods have been described with reference to “hue shift” setting. It is understood, however, that they may be used when many other settings are modified and that present systems and methods are not limited to correcting image processing parameters that control any particular aspect of image appearance or image color.

Another example can be described using the “annotation” feature, which is provided by many document editing programs to allow a user to highlight identified portions of a document using a selected color. A user may wish to apply annotation to selected document text and also modify some other aspect of the appearance of the document. Using currently available systems, any user-defined adjustments that are applied after the annotation will typically be applied to the annotated text and will also change its color. For example, annotation may be applied to the document text using light green (L*=80, a*=−80, b*=0). If the user later decides to shift the overall brightness of the document by +20, the new color value for the annotation (L*=100, a*=−80, b=0) would cause the highlighting to appear as a lighter green than the previous color.

Upon receiving the user selected annotation color (i.e., 80, −80, 0), present systems and methods would calculate a counter-shift color value of (60, −80, 0), which would then be assigned to each pixel in the annotation region. Accordingly, when the user later increases the brightness level for the image, the highlighting would be displayed in the color that was selected by the user.

It will be appreciated that various of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A system, comprising:
a scan image capture board configured to generate a digital image that represents an image on an original document; and
an image processor configured to receive said digital image and prepare said digital image for output, said image processor being further configured to receive an electronic signal associated with a custom image adjustment setting, to calculate a counter-shift image data value corresponding to said received signal and to assign said counter-shift image data value to pixels in said digital image that are selected for processing during an early applied imaging process.

2. A system as claims in claim 1 wherein said image processor is further configured to calculate a provide a custom image data value corresponding to said received signal and to assign said custom image data value to pixels in said digital image that are selected for processing during a custom imaging process.

3. A system as claims in claim 2 wherein said custom image data value provides a color value for an image data pixel.

4. A system as claimed in claim 3 wherein said custom image data value provides a hue angle for an image data pixel.

5. A system as claimed in claim 3 wherein said custom image data value provides a saturation level for an image data pixel.

6. A system as claims in claim 2 further comprising a video monitor configured to receive image data from said image processor and display a video representations of said received image data.

7. A system as claims in claim 2 further comprising a printer configured to receive image data from said image processor and generate hardcopy reproductions of said received image data.

8. A system as claims in claim 2 wherein said early applied imaging process is automatically applied to said digital image.

9. A system as claims in claim 2 wherein said custom imaging process is applied to said digital imageafter receiving user input.

10. An image processor, comprising:
an image data input configured to receive a digital image;
a user input signal processor configured to receive an electronic signal associated with a user manual adjustment and provide a customized parameter setting corresponding to said user manual adjustment;
a color value correction generator configured to calculate a counter-shift color value setting for pixels in said digital image that are selected for processing during an early applied imaging process;
a color value modifier configured to assign said counter-shift color value setting to said first imaging process selected pixels; and
an custom output processor configured to perform a custom imaging process on said digital image using at least said customized parameter setting.

11. An image processor as claimed in claim 10 wherein said color value correction generator is further configured to calculate a counter-shift color value setting for pixels in said digital image that are selected for processing during an imaging process that is automatically applied to said digital image.

12. A method, comprising:
receiving a digital image;
obtaining a customized parameter setting for a second imaging process;
using said customized parameter setting to calculate a counter-shift color value for pixels in said digital image that are selected for processing during an early applied imaging process;
assigning said counter-shift color value to said first imaging process selected pixels; and
performing said second imaging process on said digital image using at least said customized parameter setting.

13. A method as claimed in claim 12 wherein said first imaging process is automatically applied to said digital image.

14. A method as claimed in claim 12 wherein said first imaging process is a white masking process.

15. A method as claimed in claim 12 wherein said first imaging process is an image annotation process.

16. A method as claimed in claim 12 wherein said customized parameter setting is obtained from signals generated in response to user input at a user interface.

17. A method as claimed in claim 12 wherein said second imaging process is applied to modify an aspect of the color of said digital image.

18. A method as claimed in claim 17 wherein said second imaging process is applied to modify the brightness or contrast of said digital image.

19. A method as claimed in claim 17 wherein said second imaging process is applied to modify the hue of said digital image.

20. A method as claimed in claim 17 wherein said second imaging process is applied to modify the saturation of said image.
